(19) United States
(12) Patent Application Publication
(10) Pub. No.: US 2009/0081940 A1
(43) Pub. Date: Mar. 26, 2009

(54) Outdoor unit of air conditioner

(76) Inventors: Seok Hoon Jang, Gimhae-si (KR); Byoung Sup Kim, Gimhae-si (KR); Joon Hyuk Kwon, Changwon City (KR); Woong Seok Noh, Namyangju-si (KR); Eun Seong Pack, Geurnjeong-gu (KR)

Correspondence Address: MCKENNA LONG & ALDRIDGE LLP, 1900 K STREET, NW, WASHINGTON, DC, 20006, US

(21) Appl. No.: 12/081,411

(22) Filed: Apr. 15, 2008

(30) Foreign Application Priority Data
Sep. 21, 2007 (KR) 10-2007-0097001

(51) Int. Cl. H05K 5/00

(52) U.S. Cl. 454/184

(57) ABSTRACT

An outdoor unit for an air conditioner is provided. The outdoor unit has a blower fan and a control box. The blower fan forcibly discharges air upward. The control box is provided below the blower fan, and includes a plurality of built-in electronic components. The control box has an interior partitioned into a plurality of compartments to install the electronic components in, and defines air passages to dissipate heat generated by the electronic components.

### CROSS-REFERENCE TO RELATED APPLICATIONS

The present application claims priority to Korean Patent Application No. 10-2007-0097001, filed Sep. 21, 2007, which is hereby incorporated by reference in its entirety.

### BACKGROUND

The present disclosure relates to an outdoor unit of an air conditioner having a control box with an internal configuration divided into multiple compartments to form air passages through which air flows, and allow heat generated by internal electrical components to be effectively dissipated.

In general, an air conditioner is a cooling/heating system that cools an indoor environment by continually performing a cycle of suctioning warm air from the indoor environment, performing heat exchange between the air and cold refrigerant, and expelling the cooled air back into the indoor environment. For heating, reverse conditions are employed to heat the indoor environment. The air conditioner performs sequential cycles using a compressor, condenser, expansion valve, and evaporator.

Such air conditioners may be divided largely into split system air conditioners with an outdoor unit and an indoor unit installed separately from each other, and integrated air conditioners with the outdoor unit integrally installed with the indoor unit.

A relatively recent phenomenon is the widespread use of multi unit air conditioners that are effectively applied in households wanting to install two or more air conditioners, and in buildings with multiple offices that respectively require an air conditioner. A multi unit air conditioner connects one outdoor unit to a plurality of indoor units to achieve the same effect as installing a plurality of split system air conditioners.

In the different types of air conditioners described above, a plurality of electrical components is housed in a control box within the outdoor unit. Such control boxes may not be able to perform their functions properly due to excessive heat they may radiate. That is, when the electrical components generate heat when the air conditioner operates, the heat cannot be properly dissipated, causing the equipment to malfunction.

### SUMMARY

Embodiments provide an outdoor unit of an air conditioner with a control box partitioned into a plurality of installation spaces to separate each electronic component.

Embodiments also provide an outdoor unit of an air conditioner with air passages formed within the control box through which air can flow, in order to facilitate dissipation of heat generated by each electronic component therein.

In one embodiment, an outdoor unit of an air conditioner includes: a blower fan forcibly discharging air upward; and a control box provided below the blower fan, and including a plurality of built-in electronic components, wherein the control box has an interior partitioned into a plurality of compartments to install the electronic components in, and defines air passages to dissipate heat generated by the electronic components.

In another embodiment, an outdoor unit for an air conditioner, includes: a blower fan forcibly discharging air upward; and a control box provided below the blower fan, and including a plurality of built-in electronic components, wherein the control box has an interior partitioned into a plurality of compartments to install the electronic components in, and defines an air passage to dissipate heat generated by the electronic components, and the control box further includes a rear passage defined in a rear surface thereof, the rear passage guiding a flow of air.

In a further embodiment, an outdoor unit for an air conditioner, includes: a blower fan forcibly discharging air upward; and a control box provided below the blower fan, and including a plurality of built-in electronic components, wherein the control box has an interior partitioned into a plurality of compartments to install the electronic components in, and defines air passages to dissipate heat generated by the electronic components, and the control box further includes a heat sink at a rear surface thereof to dissipate heat.

In an outdoor unit of an air conditioner according to the present disclosure, the inside of a control box is partitioned into a plurality of compartments to install electrical components in positions separated from one another. Accordingly, effects of heat generated by each electrical component on other components are reduced.

Also, air passages are formed inside the control box according to the present disclosure, and outside air flows in through the air passages. Thus, electronic components inside the control box are able to easily dissipate heat due to the airflow.

Further, because heat is effectively dissipated from electronic components within the control box in the outdoor unit of an air conditioner according to the present disclosure, equipment malfunctions can be prevented, and the overall performance of the air conditioner can be improved.

The details of one or more embodiments are set forth in the accompanying drawings and the description below. Other features will be apparent from the description and drawings, and from the claims.

### BRIEF DESCRIPTION OF THE DRAWINGS

FIG. 1 is a perspective view of an outdoor unit according to a preferred embodiment of the present disclosure.

FIG. 2 is an exploded perspective view of an outdoor unit according to a preferred embodiment of the present disclosure.

FIG. 3 is a right-side view showing an installed control box according to an embodiment of the present disclosure.

FIG. 4 is a right-side sectional view showing the internal structure of a control box according an embodiment of the present disclosure.

FIG. 5 is a right-side sectional view showing the internal structure of a control box according another embodiment of the present disclosure.

FIG. 6 is a right-side sectional view showing the internal structure of a control box according a further embodiment of the present disclosure.

### DETAILED DESCRIPTION OF THE EMBODIMENTS

Reference will now be made in detail to the embodiments of the present disclosure, examples of which are illustrated in the accompanying drawings.

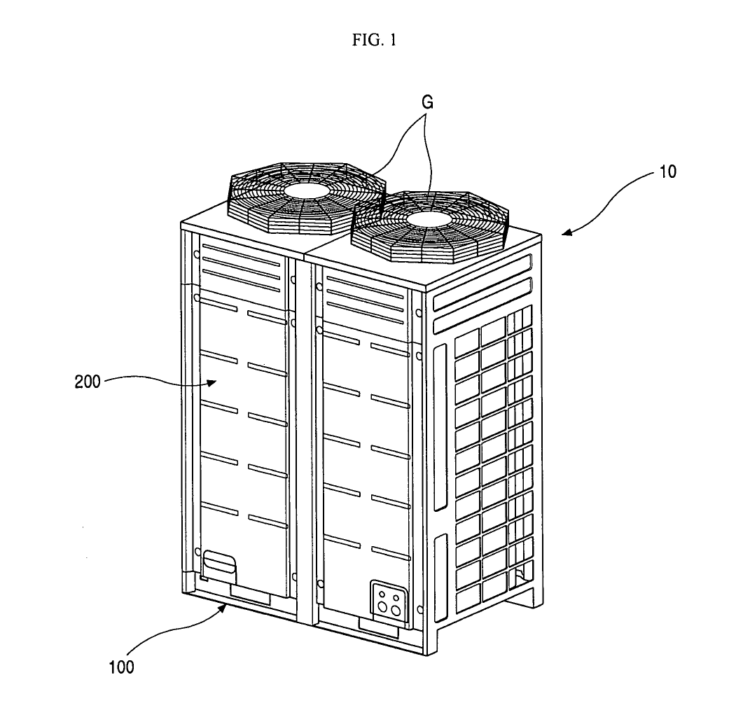

FIG. 1 is a perspective view of an outdoor unit according to a preferred embodiment of the present disclosure. Specifically, FIG. 1 exemplarily shows a type of outdoor unit for an air conditioner that discharges air upwards.

As shown in FIG. 1, the outdoor unit 10 has a hexahedral exterior shape and is connected through pipes to a plurality of indoor units (not shown). Refrigerant flows between the outdoor unit and indoor units.

The outdoor unit 10 has its lower exterior defined by a base assembly 100, and includes a cabinet 200 provided above the base assembly 100 to form the remaining exterior thereof. Also, outlet grills G have an octagonal shape (when viewed from above) and protrude upward from the top of the cabinet 200 to discharge air upward through the outlet grills G.

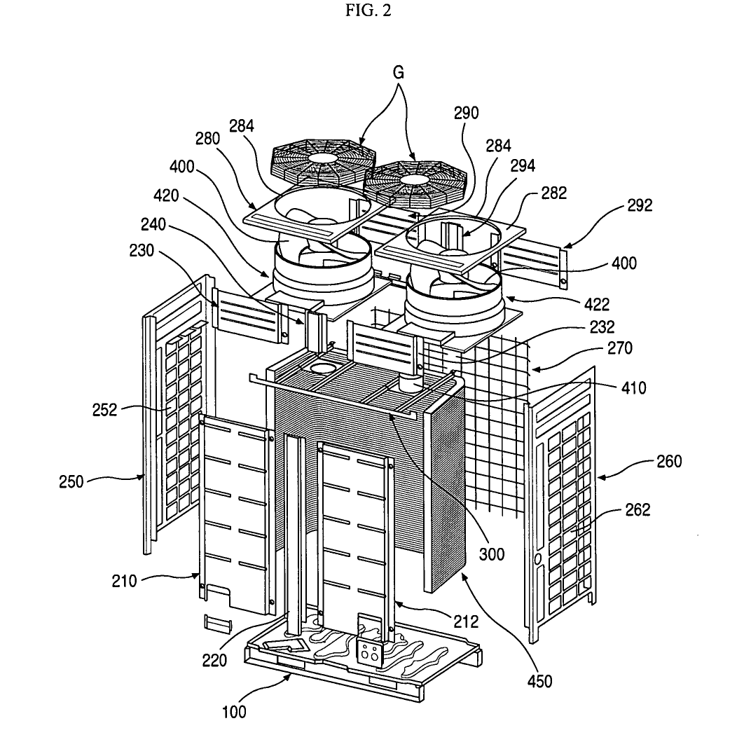

FIG. 2 is an exploded perspective view of an outdoor unit 10 according to a preferred embodiment of the present disclosure.

As shown in FIG. 2, the cabinet 200 is formed with a plurality of panels. In more detail, a pair of front panels 210 and 212 is provided at the front end of the base assembly 100 to define the front exterior of the outdoor unit. That is, a front left panel 210 and a front right panel 212, which have shapes of rectangular flat plates, are provided as a pair installed on the left and right, and a front center frame 220 is vertically elongated between the front left panel 210 and the front right panel 212.

A pair of front upper panels 230 and 232 is further provided above the pair of front panels 210 and 212. The front upper panels 230 and 232 form the front upper exterior of the outdoor unit, and include a front upper left panel 230 and a front upper right panel 232 at the left and right, respectively. A front upper frame 240 is further provided between the front upper left panel 230 and the front upper right panel 232. The front upper frame 240 is shaped correspondingly to the front center frame 220, and supports the pair of front upper panels 230 and 232.

A left panel 250 and a right panel 260 are provided at the left and right ends, respectively, of the base assembly 100, defining the left and right external facets of the outdoor unit. Also, a left grill 252 is integrally formed with the left panel 250, and a right grill 262 is integrally formed with the left panel 260. Thus, outside air is able to enter the outdoor unit 10 through left grill 252 and the right grill 262.

A pair of rear grills 270 is provided at the upper rear end of the base assembly 100. The rear grills 270 define the rear exterior surface, and air enters the outdoor unit 10 from the rear thereof through the rear grills 270.

A rear center frame (not shown) is further provided at the central portion of the pair of rear grills 270 opposite the front center frame 220 to support the pair of rear grills 270.

A pair of top panels 280 and 282 is provided between the top ends of the left panel 250 and the right panel 260 to define the top exterior of the outdoor unit. That is, the external top surface of the outdoor unit 10 is defined by the rectangular left top panel 280 and right top panel 282. An outlet 284 is defined vertically through each of the pair of top panels 280 and 282.

Also, the outlet grills (G) are installed on the outlets 284. The outlet grills (G) prevent impurities from the outside from entering through the outlets 284, and also allow air inside to be discharged upwards.

A pair of rear upper panels 290 and 292 is further provided at the top of the pair of rear grills 270. The rear upper panels 290 and 292 define the rear upper exterior of the outdoor unit, and are formed to correspond in shape to the front upper panels 230 and 232.

Accordingly, the rear upper panels 290 and 292 include a rear upper left panel 290 and a rear upper right panel 292 at the left and right sides, and a rear upper frame 294 is further provided between the rear upper left panel 290 and the rear upper right panel 292. The rear upper frame 294 is formed in a shape corresponding to the front upper frame 240, and supports the pair of rear upper panels 290 and 292.

A frame assembly 300 is provided within the cabinet 200. The frame assembly 300 is for supporting shrouds 420 and 422, a blower fan 400, and other components (to be described below), and is installed on the top ends of the front panels 210 and 212.

A pair of blower fan 400 and fan motor 410 assemblies is installed at the top of the frame assembly 300. The pair of blower fans 400 is enclosed by a pair of shrouds 420 and 422. That is, a left shroud 420 and a right shroud 422 having the same shape are installed at the top of the frame assembly 300, and a blower fan 400 is disposed to the inside of the pair of shrouds 420 and 422.

A heat exchanger 450 is installed within the cavity 200. The heat exchanger 450 functions to exchange heat between refrigerant flowing therein and air from the outside, and is installed on the upper left end, rear end, and right end of the base assembly 100. That is, the heat exchanger 450 is formed in a nA, shape as shown (when viewed from above).

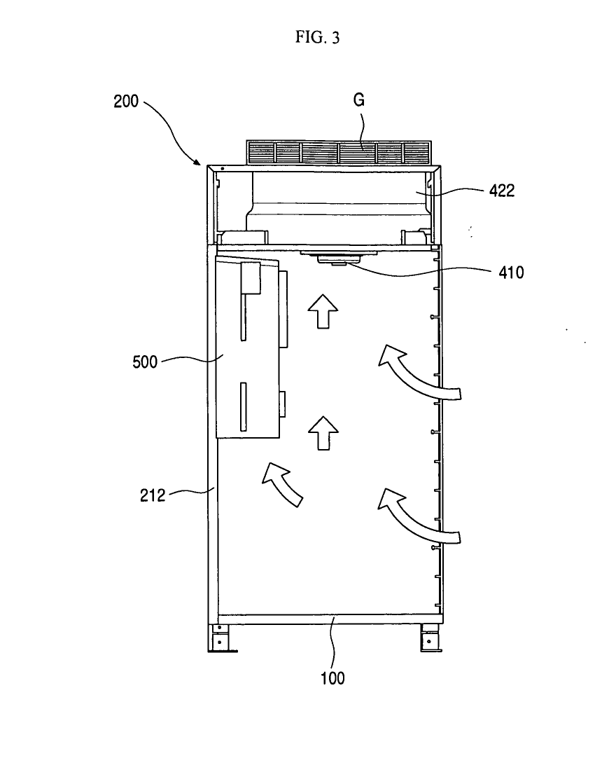

FIG. 3 is a right-side (sectional) view of a control box 500 installed the cabinet 200 according to an embodiment of the present disclosure.

As shown in FIG. 3, the control box 500 is installed rearward of the front panels 210 and 212. The control box 500 is a portion that controls the operation of the air conditioner, and has a plurality of electronic components within. Also, the blower fans 400 are disposed above the control box 500. Therefore, after air outside the outdoor unit 10 enters the outdoor unit 10, it is discharged upward, as shown in FIG. 3.

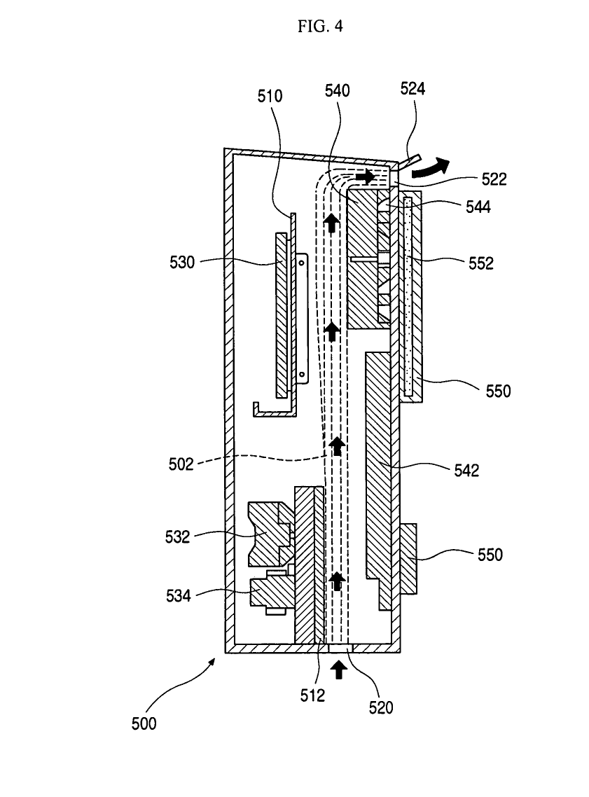

FIG. 4 is a right-side sectional view showing the internal structure of a control box according an embodiment of the present disclosure.

The inside of a control box 500 is partitioned into a plurality of compartments in which electronic components are installed, and form air passages 502 to dissipate heat generated by the components.

In further detail, an upper supporting plate 510 and a lower supporting plate 512 for installing components are provided at the central portion within the control box 500. The upper supporting plate 510 and the lower supporting plate 512 are formed in rectangular plate shapes, and partition the inner space of the control box 500 roughly into a front compartment (on the left in FIG. 4) and a rear compartment (on the right in FIG. 4).

The upper supporting plate 510 and the lower supporting plate 512 in FIG. 4 are installed to be separated from one another. Alternately, however, the upper supporting plate 510 and the lower supporting plate 512 may be connected or integrally formed.

Between the upper supporting plate 510 and the lower supporting plate 512 and the rear surface (at the right in FIG. 4), a predetermined space is defined. An air passage is defined vertically by the space. That is, an air passage 502 is formed, through which air from the outside that enters an inlet 520 (to be described below) ascends.

In more detail, air that enters through one end (the lower end) of the control box 500 passes along the air passage 502 and is discharged through the other end (the upper or rear end).

Accordingly, the inlet 520 and an outlet 522, for air entry and discharge, are respectively formed in the control box 500. The inlet 520 and outlet 522 are defined in different surfaces. That is, the inlet 520 is formed vertically through the lower surface of the control box 500, and the outlet 522 is formed from front to rear through the rear surface (the right surface in FIG. 4) at the upper portion of the control box 500.

In addition, a rain blocker 524 for preventing the entry of rainwater is further formed on the outlet 522. That is, because rainwater can enter the control box 500 from the outside through the outlet 522 formed at the rear surface (or right surface in FIG. 4) of the control box 500, the rain blocker 524, for preventing infiltration of rainwater, is formed to extend rearward on the outlet 522.

The rain blocker 524 may be sloped so that its position rises gradually toward the rear (the right in FIG. 4). This is to allow air discharged rearward (to the right in FIG. 4) through the outlet 522 to be smoothly expelled upward from the outdoor unit 10.

A plurality of electronic components is installed within the control box 500. Of these, the components that generate comparatively less heat are installed in the front portion (the left in FIG. 4), and the components that generate comparatively more heat are disposed in the rear portion (the right in FIG. 4).

Specifically, a main printed circuit board (PCB) 530, a terminal block 532, and a magnet switch (SW) 534 are installed in the front portion (the left side in FIG. 4) of the control box 500. That is, a main PCB 530 is installed on the left surface of the upper supporting plate 510, and the terminal block 532 and magnet S/W 534, etc. are installed on the left surface of the lower supporting plate 512.

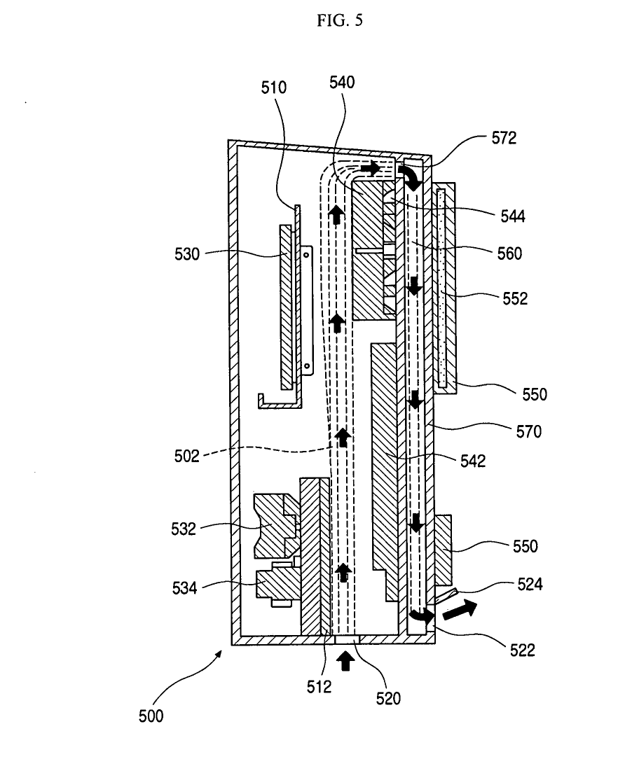

Furthermore, components such as a reactor 540 and inverter PCB (not shown), a noise filter 542, etc. are installed in the rear portion (the right side in FIG. 4) of the control box 500. That is, the reactor 540 and inverter PCB are installed at the rear (the right side in FIG. 5) surface in the upper portion of the control box 500, and the noise filter 542 is installed at the lower portion thereof.

Moreover, a heat sink 550 for dissipating heat is provided at the rear surface (the left surface in FIG. 4) of the control box 500. The heat sink 550 includes a plurality of heat dissipating fins, and projects rearward (to the left in FIG. 4) from the control box 500.

A heat pipe 552 through which refrigerant flows is located within the heat sink 550. The heat pipe 552 consists of a thin pipe that extends vertically, and refrigerant is filled inside the heat pipe 552.

Accordingly, the refrigerant filled in the heat pipe 552 flows vertically to uniformly transfer heat to the heat sink 550 in a vertical direction. Thus, the heat sink 550 may be provided in plurality, so that heat can be dissipated evenly along the entire surface area of the heat sink 550.

A plurality of heat dissipating ribs 544 is further provided at the rear end (the right end in FIG. 4) of the reactor 540, to support the reactor 540 and aid in heat dissipation.

FIG. 5 is a view of a control box 500 according another embodiment of the present disclosure. Below, a description on the configuration of the control box 500 will be provided, and like reference numerals will be used for elements that perform the same functions in FIG. 4, and repetitive description thereof will not be provided.

Referring to FIG. 5, a rear passage 560 for guiding the flow of air is further formed in the rear surface of the control box 500.

In detail, a further space is formed in the rear surface (the right in FIG. 5) of the control box 500, the space being a rear passage 560 for guiding the flow of air.

Accordingly, the reactor 540, noise filter 542, etc. described above are mounted on a separate rear supporting plate 570 partitioning the inner space, and an air through-hole 572 is defined from front to rear through the upper end of the rear supporting plate 570.

Also, the outlet 522 is defined through the bottom end (the right surface in FIG. 5) of the control box 500, and a rain blocker 524 is formed on the outlet 522.

Accordingly, with reference to the structure shown in FIG. 5, outside air that enters from the bottom of the control box 500 through the inlet 520 flows upward through the air passage 502, and then passes through the lower supporting plate 570 through the air through-hole 572 and flows to the rear (the right in FIG. 5), and flows downward along the rear passage 560, to be discharged to the outside of the control box 500 through the outlet 522.

The flow of air in an outdoor unit of an air conditioner configured above according to the present disclosure will be addressed in detail below.

First, referring to FIG. 3, the overall flow of air throughout the inside of the outdoor unit 10 is an upward airflow within the outdoor unit 10, induced by the rotation of the blower fan 400.

Accordingly, the outdoor air flows into the outdoor unit 10 through the rear grill 270, left grill 252, and right grill 262. The air is suctioned by the blower fan 400, moves upward to flow into the shrouds 420 and 422, and is discharged upward through the outlet grill G.

Here, external air contacts the outer surface of the control box 500 in a primary stage, and during this process, heat exchange occurs by means of the heat sink 550 formed on the outside of the control box 500. Also, the heat pipe 552 within the heat sink 550 increases the heat exchanging effectiveness of the heat sink 550 (see FIG. 4).

Next, FIG. 4 will be referred to in describing the flow of air within the control box 500. Here, the blower fan 400 forcibly circulates airflow in an upward direction, and the discharging of air through the outlet 522.

Accordingly, air is suctioned through the inlet 520, and the air suctioned through the inlet 520 flows upward through the air passage 502, after which it passes through the outlet 522 to be discharged to the rear (the right side in FIG. 4) of the control box 500. Then, the air enters the shrouds 420 and 422, and is discharged to the upper portion of the outdoor unit 10.

Also, as shown in FIG. 5, the air that enters through the inlet 520 flows upward through the air passage 502, and then passes through the air through-hole 572 and flows downward again through the rear passage 560, after which the air flows through the outlet 522 and is discharged to the rear (the right in FIG. 5) of the control box 500, and is discharged from the top of the outdoor unit 10.

Although embodiments have been described with reference to a number of illustrative embodiments thereof, it should be understood that numerous other modifications and embodiments can be devised by those skilled in the art that will fall within the spirit and scope of the principles of this disclosure.

For example, while in the above embodiments, the air that enters through the inlet 520 of the control box 500 has been exemplarily described as being discharged rearward of the control box 500, such formed locations of the inlet 520 and outlet 522 may be altered in various ways.

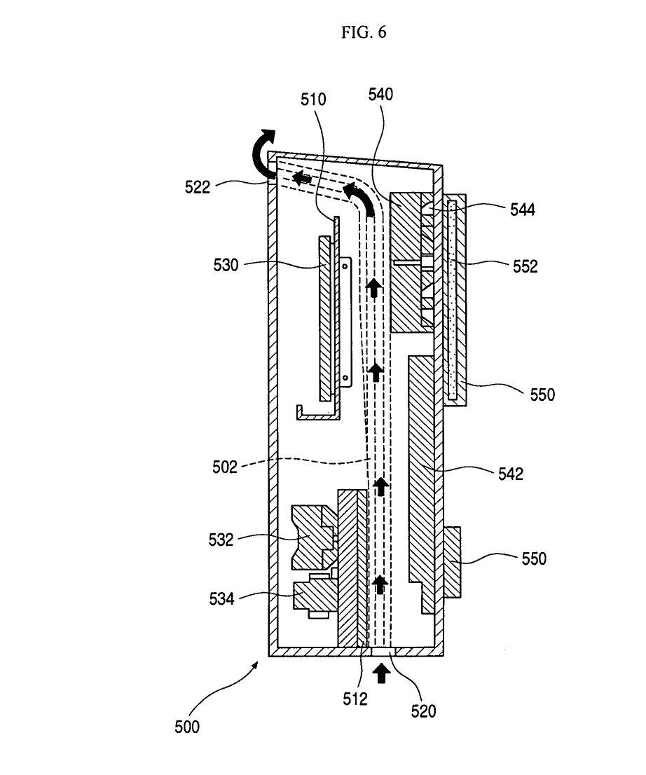

FIG. 6 shows an example of the outlet 522 formed in the front (right side in FIG. 6) of a control box 500. In this case, other elements are the same as their counterparts in FIG. 4 with respect to configuration and application, with an exception being that after the air that enters through the inlet 520 flows upward through the air passage 502, the air is discharged to the front (left side in FIG. 5) of the control box 500 through the outlet 522 and discharged upward from the outdoor unit 10.

Also, in contrast to the above-described embodiments, it will be apparent that the inlet and outlet may be defined in different surface regions to alter the flow direction of air. That is, the inlet may alternately be defined in a side surface or a rear surface of the control box 500, and the outlet may be formed in both the left surface and right surface or in both the front surface and rear surface.

What is claimed is:

1. An outdoor unit for an air conditioner, comprising
a blower fan forcibly discharging air upward; and
a control box provided below the blower fan, and including a plurality of built-in electronic components,
wherein the control box has an interior partitioned into a plurality of compartments to install the electronic components in, and defines an air passage to dissipate heat generated by the electronic components.

2. The outdoor unit according to claim 1, wherein air that enters through one end of the control box flows along the air passage and is discharged through the other end of the control box.

3. The outdoor unit according to claim 2, wherein the control box defines an inlet and an outlet in different surfaces from one another, the inlet and outlet admitting and discharging air, respectively.

4. The outdoor unit according to claim 2, wherein those of the electronic components generating less heat are disposed in a front portion of the control box, and those of the electronic components generating more heat are disposed in a rear portion of the control box.

5. An outdoor unit for an air conditioner, comprising:
a blower fan forcibly discharging air upward; and
a control box provided below the blower fan, and including a plurality of built-in electronic components, wherein
the control box has an interior partitioned into a plurality of compartments to install the electronic components in, and defines an air passage to dissipate heat generated by the electronic components, and
the control box further includes a rear passage defined in a rear surface thereof, the rear passage guiding a flow of air.

6. The outdoor unit according to claim 5, wherein the control box defines an inlet and an outlet in different surfaces from one another, the inlet and outlet admitting and discharging air, respectively.

7. The outdoor unit according to claim 6, wherein the inlet is defined in a lower surface of the control box, and the outlet is defined in a rear surface of the control box.

8. The outdoor unit according to claim 7, further comprising a rain blocker formed at the outlet to prevent entry of rain water.

9. The outdoor unit according to claim 8, wherein the rain blocker is formed projecting rearward from a rear surface of the control box.

10. The outdoor unit according to claim 9, wherein the rain blocker is formed to progressively rise gradually in a rearward direction.

11. An outdoor unit for an air conditioner, comprising:
a blower fan forcibly discharging air upward; and
a control box provided below the blower fan, and including a plurality of built-in electronic components, wherein
the control box has an interior partitioned into a plurality of compartments to install the electronic components in, and defines air passages to dissipate heat generated by the electronic components, and
the control box further includes a heat sink at a rear surface thereof to dissipate heat.

12. The outdoor unit according to claim 11, wherein the heat sink comprises a built-in heat pipe through which refrigerant flows.

13. The outdoor unit according to claim 12, wherein the heat sink comprises a plurality of heat dissipating fins.

14. The outdoor unit according to claim 12, wherein the heat pipe is elongated vertically, and is filled with refrigerant.
